(19) United States
(12) Patent Application Publication
(10) Pub. No.: US 2024/0145804 A1
(43) Pub. Date: May 2, 2024

(54) METHOD FOR DISASSEMBLING LITHIUM ION SECONDARY BATTERY

(71) Applicant: TOYOTA JIDOSHA KABUSHIKI KAISHA, Toyota-shi (JP)

(72) Inventors: Keisuke ISOMURA, Kariya-shi (JP); Kenichiro MURAMATSU, Toyota-shi (JP); Kazuki NORITAKE, Nagoya-shi (JP)

(73) Assignee: TOYOTA JIDOSHA KABUSHIKI KAISHA, Toyota-shi (JP)

(21) Appl. No.: 18/449,185

(22) Filed: Aug. 14, 2023

(30) Foreign Application Priority Data
Nov. 2, 2022 (JP) 2022-176595

(51) Int. Cl. H01M 10/54; G01R 31/388

(52) U.S. Cl. CPC H01M 10/54; G01R 31/388; H01M 10/0525

(57) ABSTRACT

A method for disassembling a lithium ion secondary battery of the present disclosure includes a discharging step, a primary crushing step, a drying step, and a secondary crushing step. In the discharging step, the lithium ion secondary battery is discharged such that the voltage of the lithium ion secondary battery is not lower than 0.8 V, and preferably the voltage is lower than or equal to 3.0 V. In the primary crushing step, the case is crushed to expose the electrode body. In the drying step, the electrode body is dried until the high-boiling-point solvent contained in the electrolytic solution evaporates. Then, in the secondary crushing step, the electrode body after drying is crushed and the separator is peeled off from the electrode.

### CROSS-REFERENCE TO RELATED APPLICATION

This application claims priority to Japanese Patent Application No. 2022-176595 filed on Nov. 2, 2022, incorporated herein by reference in its entirety.

### BACKGROUND

### 1. Technical Field

The present disclosure relates to a method for disassembling a lithium ion secondary battery accommodated in a case in a state where an electrode body in which an electrode and a separator are laminated is impregnated in an electrolyte solution containing a low-boiling-point solvent and a high-boiling-point solvent.

### 2. Description of Related Art

Japanese Unexamined Patent Application Publication No. 2021-072157 (JP 2021-072157 A) discloses a method of discharging and disassembling a used lithium ion secondary battery and separating and recovering a battery material containing an active material. The method disclosed in JP 2021-072157 A includes starting a disassembly operation at a stage where the voltage is equal to or less than a voltage at which no spark is generated by performing discharge, and ending the disassembly operation at a stage where there is no contamination due to elution of copper or at a stage where the contamination is minor.

In the recycling of a lithium ion secondary battery, it is required to enhance the recoverability of an expensive active material while ensuring safety. In order to improve the recoverability of the active material, it is important to facilitate separation of the separator from the electrode. The electrode and the separator are bonded to each other with an adhesive to form an electrode body. When the electrode body is pulverized, if the separator is not separated from the electrode, the active material adheres to the separator. It is not easy to peel off the active material adhered to the separator.

The method disclosed in JP 2021-072157 A has room for improvement in the recoverability of the active material. One reason for this is that, in the process disclosed in JP 2021-072157 A, the voltage is reduced to 0.6 V or lower when the lithium ion secondary battery is disassembled. Experiments according to the present disclosure have shown that excessively reducing the voltage tends to cause the active material to easily adhere to the separator. In addition, although the electrode body is impregnated with an electrolyte solution containing a solvent, it has also been found that there is a difference in the ease of separation of the separator from the electrode depending on the method of treating the electrolyte solution. However, in the method disclosed in JP 2021-072157 A, the treatment of the electrolyte solution is not particularly considered.

As a document showing the state of the art related to the technical field related to the present disclosure, Japanese Unexamined Patent Application Publication No. 2012-195073 (JP 2012-195073 A) can be exemplified in addition to JP 2021-072157 A.

### SUMMARY

The present disclosure has been made in view of the above problems. One object of the present disclosure is to improve the recoverability of an active material contained in an electrode by making it possible to easily separate a separator from an electrode in disassembling a lithium ion secondary battery.

The present disclosure provides a method for disassembling a lithium ion secondary battery for achieving the above object. A method for disassembling a lithium ion secondary battery of the present disclosure is a method for disassembling a lithium ion secondary battery accommodated in a case in a state where an electrode body in which an electrode and a separator are laminated is impregnated in an electrolyte solution containing a low-boiling-point solvent and a high-boiling-point solvent. The method of the present disclosure includes a discharging step, a primary crushing step, a drying step, and a secondary crushing step. The discharging step is a step of discharging the lithium ion secondary battery such that a voltage of the lithium ion secondary battery does not fall below 0.8 V. The primary crushing step is a step of crushing the case to expose the electrode body. The drying step is a step of drying the exposed electrode body until the high-boiling-point solvent evaporates. The secondary crushing step is a step of crushing the electrode body after being dried and separating the separator from the electrode.

According to the method of the present disclosure, it is possible to suppress the active material from adhering to the separator by discharging the lithium ion secondary battery so that the voltage does not fall below 0.8 V. The electrode body is then exposed, dried, and the high-boiling-point solvent contained in the electrolyte solution is evaporated, whereby the active material can be easily peeled off from the separator. Therefore, the electrode body after being dried is in a state where the separator can be easily separated from the electrode, and the active material contained in the electrode can be recovered with a high recovery rate.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a disassembly process of a lithium ion secondary battery according to an embodiment of the present disclosure;

FIG. 2 is a diagram showing a result of confirming a relationship between a voltage and a heat generation temperature in a nail penetration test;

FIG. 3 is a diagram showing a result of confirming a preferable discharge condition from the viewpoint of recoverability of the positive electrode active material;

FIG. 4 is a graph showing the relationship between the dry state of the electrode assembly and the peelability of the separator and the recoverability of the electrolyte solution; and

FIG. 5 is a diagram showing a peeling test of the electrode assembly after discharging under appropriate discharging conditions and evaporating the electrolyte solution.

### DETAILED DESCRIPTION OF EMBODIMENTS

### 1. Lithium Ion Secondary Battery

The lithium ion secondary battery is used by connecting a plurality of cells. The lithium ion secondary battery to be disassembled in the present embodiment is a cell. Hereinafter, a lithium ion secondary battery to be disassembled may be referred to as a cell.

The cell includes an electrode body formed by laminating an electrode and a separator. The electrode includes a positive electrode and a negative electrode. The separator is a resin film that disconnects the positive electrode and the negative electrode. The electrode body is stored in the case in a state of being impregnated with the electrolytic solution. For example, an aluminum laminate material in which a resin is adhered to both surfaces of aluminum is used as the case.

The positive electrode of the electrode includes a current collector made of aluminum foil and a positive electrode active material applied to the surface of the current collector. Typically, lithium oxide such as lithium cobaltate, lithium manganate, or ternary lithium oxide is used as the positive electrode active material. The negative electrode of the electrode includes a current collector made of copper foil and a negative electrode active material applied to the surface of the current collector. As the negative electrode active material, typically, a carbon-based material such as graphite or hard carbon is used.

The electrolytic solution is a solution obtained by dissolving a lithium-containing salt in a solvent. The solvent consists of a low boiling point solvent and a high boiling point solvent. Examples of the low boiling point solvents include dimethyl carbonate (DMC), ethyl methyl carbonate (EMC), and diethyl carbonate (DEC). Examples of the high boiling point solvents include ethylene carbonate (EC) and propylene carbonate (PC). In the present embodiment, DMC and EMC are used as the low-boiling point solvent, and EC is used as the high-boiling point solvent.

### 2. Cell Dismantling Process

The dismantling of the cell is performed for the purpose of taking out a recyclable substance from various substances constituting the cell and safely recovering a harmful substance. The material to be recycled is an expensive positive electrode active material and is recovered in the form of a black mass. Iron, copper, and aluminum are also collected for recycling. The resin film constituting the separator is recovered as waste. DMC, EMC, and EC are recovered as hazardous materials. The method for disassembling a lithium ion secondary battery of the present disclosure is applied to a disassembling step of a cell for separating and recovering these substances.

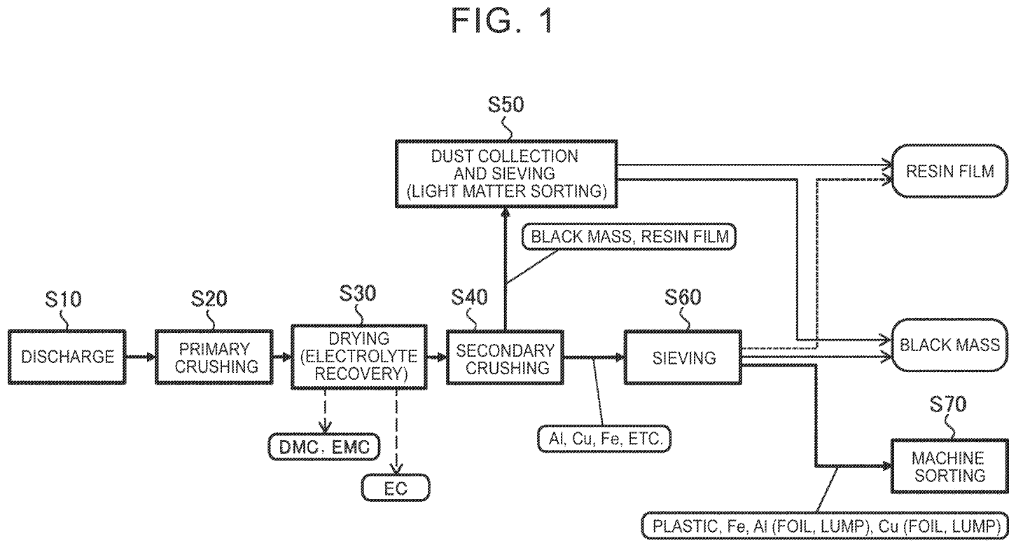

FIG. 1 shows a disassembly process of a cell according to the present embodiment. The dismantling step of the cell according to the present embodiment includes a discharging step S10, a primary crushing step S20, a drying step S30, a secondary crushing step S40, a dust collection and sieving process S50, a sieving process S60, and a mechanical sorting step S70. Hereinafter, a process of disassembling a cell according to the present embodiment will be described.

In the discharging step S10, the cells are discharged such that the voltage of the cells is equal to or higher than 0.8 V and equal to or lower than 3.0 V. The reason for discharging the cell is to prevent the separator from melting due to heat generation due to a short circuit during crushing of the cell in a subsequent process. Welding of the molten separator to the positive electrode deteriorates recyclability. 3.0 V, which is set as a criterion for completion of discharging, is approximately a voltage corresponding to SOC 0% of the cell. A range of 0% to 100% of SOC corresponds generally to a range of 3.0 V to 4.1 V.

In the discharging step S10, the cell is allowed to be overdischarged unless the voltage falls below 0.8 V. The reason why the voltage of the discharged cells does not fall below 0.8 V is to suppress the positive electrode active material from adhering to the separators. It is not easy to remove the positive electrode active material attached to the separator in a later step. However, preventing the voltage from falling below 0.8 V means that the voltage does not fall below 0.8 V continuously for a certain period of time, and the voltage is allowed to fall below 0.8 V momentarily.

In the primary crushing step S20, the case is crushed to expose the inner electrode assembly. By exposing the electrode body, the electrolyte attached to the electrode body can be evaporated and the electrode body can be dried. As a method of crushing the case, for example, a method of cutting the case by a shredder is used.

In the drying step S30, the exposed electrode assembly is dried, and the electrolyte solution is recovered in the process. The drying step S30 includes a first distillation step for recovering DMC and EMC, which are low boiling point solvents, and a second distillation step for recovering EC, which are high boiling point solvents. In the first distillation step, DMC and EMC are evaporated and recovered below the boiling point of EC. When DMC and EMC are no longer detected by the gas sensor, it may be determined that DMC and EMC have evaporated. In the second distilling step to be carried out, the remaining EC is evaporated and recovered. When EC is no longer detected by the gas sensor, it may be determined that EC has evaporated.

Thus, in the drying step S30, DMC and EMC and EC are separately distilled and recovered. However, if DMC and EMC and EC do not need to be recovered separately, or if they are to be separated by distillation in a subsequent step, the electrode assembly may be dried at a temperature higher than the boiling point of EC from the beginning. In any case, in the drying step S30, the electrode assembly is dried until EC, which is a high-boiling-point solvent, evaporates.

In the secondary crushing step S40, the dried electrode assembly is crushed to separate the separators from the electrodes, and the positive electrode active material is separated from the current collector of the positive electrode. The reason why the electrode assembly is dried until EC evaporates in the drying step S30 is to prevent the positive electrode active material from adhering to the separators and to facilitate peeling of the positive electrode active material. In the secondary crushing step S40, the crushing may be performed while the electrode assembly is heated. As a method of crushing the electrode body after drying, for example, a method of crushing the electrode body by a crusher such as a hammer crusher or a chain crusher is used.

The dust collection and sieving process S50 and the sieving process S60 are processes of sorting the crushed objects in the secondary crushing step S40. In the dust collection and sieving process S50, only light, small objects such as dust are sorted. In the sieving process S60, relatively heavy and large objects that have been crushed to a size less than or equal to a certain value are selected. In the dust collection and sieving process S50 and the sieving process S60, sieves having different sizes of eyes are used. In the dust collection and sieving process S50, fine sieves are used, and in the sieving process S60, large sieves are used.

In the dust collection and sieving process S50, the black mass and the resinous film are selected from the pulverized objects. The black mass and the resin film are further sorted by material. In the sieving process S60, an object such as aluminum, copper, iron, or the like is selected from the pulverized objects. However, since the black mass and the resin film are also mixed in them, they are separately screened and sorted for each substance. The remaining large objects, such as plastic masses, iron, aluminum (foils and masses), copper (foils and masses), are mechanically sorted by material S70 the mechanical sorting process.

### 3. Test Results

### 3-1. Test to Determine the Target Voltage in the Discharging Step

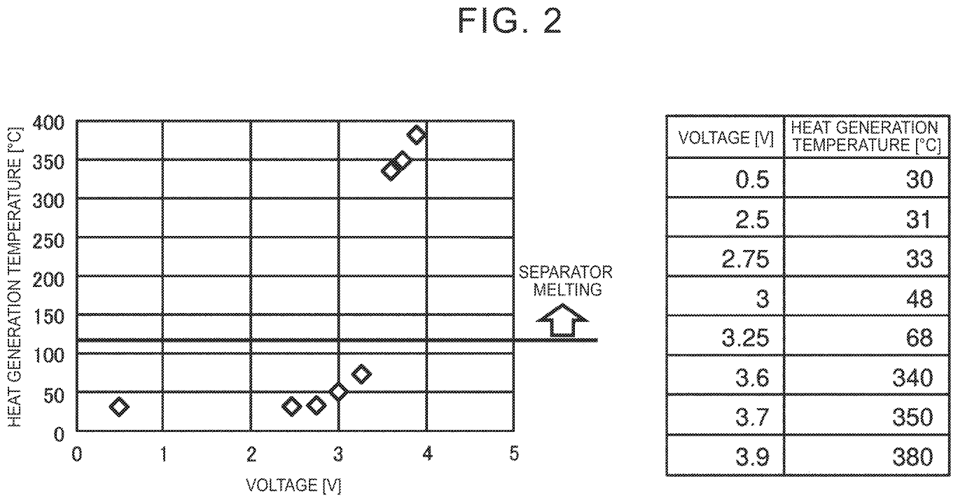

FIG. 2 is a diagram illustrating a result of checking a relationship between a voltage of a cell and a heat generation temperature in a nail penetration test. FIG. 2 shows the results of measuring the heating temperature at the time when the cell is short-circuited by piercing a nail under various voltage conditions. Since the melting temperature of the separators is 120° C., in the discharging step S10, the cell temperature needs to be lowered to a voltage that does not become higher than 120° C. at the time of crushing the cell in the primary crushing step S20. According to FIG. 2, it can be seen that the voltage at which the cell temperature is 120° C. is in 3.6 V range from 3.0 V. However, the voltage adjustment from 3.0 V to 3.6 V is difficult and unstable due to the large decreasing slope of the voltage. Therefore, in order to reliably prevent the separators from melting, in the discharging step S10, it is preferable to adjust the voltage of the cell to 3.0 V or lower.

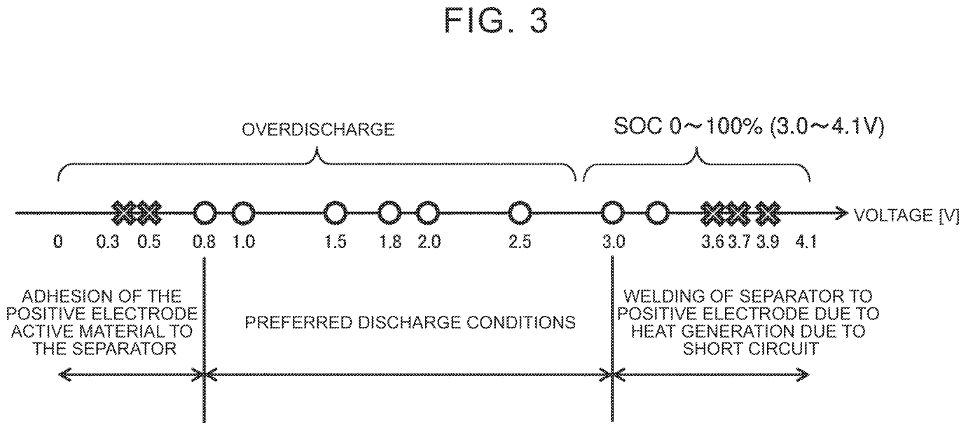

FIG. 3 is a diagram showing a result of confirming a preferable discharge condition from the viewpoint of recoverability of the positive electrode active material. In FIG. 3, the voltage marked with a circle means the voltage at which the preferred result was obtained, and the voltage marked with an X means the voltage at which the problem occurred. In the test based on the results shown in FIG. 3, the positive electrode active material was remarkably adhered to the separators for 0.3 V and 0.5 V. This is presumed to be due to the anchor effect caused by the deposition of the positive electrode active material on the positive electrode surface. Above 0.8 V, the positive electrode active material did not adhere to the separators in question. However, in the cases of 3.6 V, 3.7 V, and 3.9 V, the separator is welded to the positive electrode due to heat generation. From the above confirmation, it can be concluded that a voltage preferable as the target voltage of the cell in the discharging step S10 is a voltage equal to or higher than 0.8 V and equal to or lower than 3.0 V.

### 3-2. Test to Determine the Target Dry Condition in the Drying Step

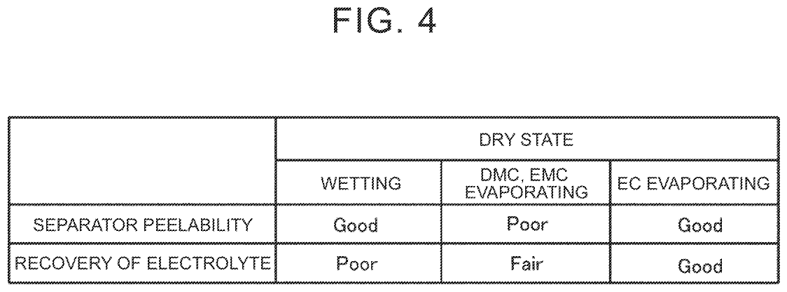

FIG. 4 is a diagram illustrating a result of confirmation of a relationship between a dry state of an electrode body, a peelability of a separator, and a recoverability of an electrolyte solution. “Wet” in the dry state of the electrode body means a state in which the electrode body is not dried at all. In this condition, not only EC, which is a high-boiling solvent, but also DMC and EMC, which are low-boiling solvents, are not evaporated. That is, the electrode body is in a wet state by the electrolytic solution. As a result of the peeling property test of the separator, it was confirmed that if the electrodes are wet with the electrolyte, the separator can be easily peeled off from the electrodes. However, this method has the disadvantage that the electrolyte cannot be recovered.

“DMC, EMC evaporation” in the dry state of the electrode body means a state in which the electrode body is dried to such an extent that DMC and EMC evaporate. In this condition, only the low-boiling solvents DMC and EMC evaporate, and the high-boiling solvent EC does not evaporate. Testing of the peelability of the separator confirmed that the positive electrode active material easily adheres to the separator when EC is not evaporated. This is presumably due to the fact that the low-viscosity DMC and EMC evaporate and only EC is deposited at the interface between the separator and the active material, so that the separator and the active material easily come into close contact with each other. In addition, in this process, DMC and EMC of the electrolyte are recovered, but EC cannot be recovered.

“EC vaporization” in a dry state of the electrode body means a state in which the electrode body is dried to such an extent that EC is vaporized. In this condition, not only DMC and EMC, which are low-boiling solvents, but also EC, which are high-boiling solvents, are evaporated. It was confirmed that the separator can be easily peeled off from the electrode when the separator is dried until EC evaporates. This process can also recover EC in addition to DMC and EMC. From the above confirmation, it can be concluded that a preferable state as the target dry state of the electrode assembly in the drying step S30 is a state in which the electrode assembly is dried until EC is evaporated.

### 3-3. Test to Confirm the Peeling Rate of the Positive Electrode Active Material

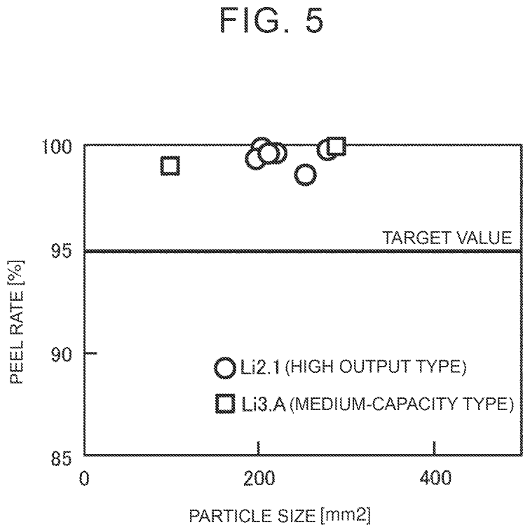

FIG. 5 is a graph showing the results of a peeling test of an electrode body after discharging under appropriate discharge conditions and evaporating an electrolyte solution. Discharging under appropriate discharge conditions means discharging so that the cell voltage becomes equal to or higher than 0.8 V and equal to or lower than 3.0 V. Evaporating the electrolyte means evaporating to EC as well as DMC and EMC.

In the peeling test, the electrode body was pulverized by a pulverizer to peel the positive electrode active material from the current collector, and the peeling rate thereof was investigated. The cells used in the peeling test are a high-power lithium ion secondary battery (Li2.1) and a medium-capacity lithium ion secondary battery (Li3.A). The horizontal axis of the graph of the test results is the particle size of the ground electrode body. The test results show that a peel rate of more than the target value of 95% is obtained in all samples. That is, from the test results, it was confirmed that the positive electrode active material can be recovered at a high recovery rate according to the disassembly step according to the present embodiment, that is, the disassembly step to which the method for disassembling the lithium ion secondary battery of the present disclosure is applied.

What is claimed is:

1. A method for disassembling a lithium ion secondary battery accommodated in a case in a state where an electrode body in which an electrode and a separator are laminated is impregnated in an electrolyte solution containing a low-boiling-point solvent and a high-boiling-point solvent, the method comprising:
a discharging step of discharging the lithium ion secondary battery such that a voltage of the lithium ion secondary battery does not fall below 0.8 V;
a primary crushing step of crushing the case to expose the electrode body;
a drying step of drying the exposed electrode body until the high-boiling-point solvent evaporates; and
a secondary crushing step of crushing the electrode body after being dried and separating the separator from the electrode.

2. The method according to claim 1, wherein the discharging step includes discharging the lithium ion secondary battery such that the voltage of the lithium ion secondary battery becomes equal to or lower than 3.0 V.

3. The method according to claim 1, wherein the drying step includes a first distillation step of recovering the low-boiling-point solvent by evaporating the low-boiling-point solvent at a temperature lower than a boiling point of the high-boiling-point solvent, and a second distillation step of recovering the high-boiling-point solvent remaining after the first distillation step by evaporating the high-boiling-point solvent.

4. The method according to claim 1, wherein the secondary crushing step includes crushing the electrode body after being dried to separate an active material constituting the electrode from a current collector constituting the electrode.
